(19) United States
(12) Patent Application Publication
(10) Pub. No.: US 2012/0103855 A1
(43) Pub. Date: May 3, 2012

(54) CASES FOR ELECTRONIC DEVICES

(75) Inventors: Scott Carter Gaddis, II, Louisville, KY (US); Steven Neel Ford, Owensboro, KY (US); Timothy Furlong, JR., Pewee Valley, KY (US)

(73) Assignee: 360 MOBILITY SOLUTIONS, LLC, Louisville, KY (US)

(21) Appl. No.: 13/290,079

(22) Filed: Nov. 5, 2011

Related U.S. Application Data
(63) Continuation-in-part of application No. 13/088,749, filed on Apr. 18, 2011.
(60) Provisional application No. 61/352,024, filed on Jun. 7, 2010.

(51) Int. Cl. B65D 81/02; B65D 51/04; H05K 5/00

(52) U.S. Cl. 206/521; 361/679.01; 220/810

(57) ABSTRACT

In one embodiment of the invention, a case for electronic devices is provided. The case has a shell and a rotatable handled rotatably coupled to the shell. The shell is adapted to partially surround an electronic device. The shell includes a first shell portion and a second shell portion adapted to couple to the first shell portion. The first shell portion has a display opening to allow a user to view the electronic device. The shell may include a camera opening to allow images to be captured by the electronic device. The rotatable handle can couple to and decouple from the second shell portion of the shell. The rotatable handle allows the shell to rotate about an axis of rotation. The rotatable handle includes an extendable strap assembly to receive a hand of a user.

### CROSS REFERENCE TO RELATED APPLICATIONS

This patent application claims the benefit and is a continuation in part (CIP) of U.S. patent application Ser. No. 13/088,749 filed by Gaddis et. al on Jun. 7, 2010 entitled ROTATABLE CASES FOR ELECTRONIC DEVICES; that claims the benefit of U.S. Provisional Patent Application Ser. No. 61/352,024 filed by Gaddis et al on Jun. 7, 2010, entitled 360 DEGREE ROTATABLE SLEEVE FOR ELECTRONIC DEVICES; both of which are incorporated herein by reference.

### TECHNICAL FIELD

The embodiments of the invention are generally related to cases for electronic devices.

### BACKGROUND

Cases for electronic devices are used by users who wish to provide protection to electronic devices, particularly for electronic devices that are portable. Cases may allow users to interact with the electronic devices through the original interface of the electronic devices, while providing resilient surfaces that protect the electronic devices from abrasion, impact, and/or compression.

As the size and weight of electronic devices grow, it may become increasingly uncomfortable for a user to support the electronic devices through grasping a case alone, with the user's fingers. Further, a user may prefer to interact and/or view the electronic device in a free-standing condition, without having to support the electronic device.

Accordingly, it is desirable to provide cases that protect electronic devices while improving ergonomics to support electronic devices with a user's hand. It is further desirable to alternately allow the electronic device to be supported with a user's hand or in a free-standing condition upon a surface.

### SUMMARY

The one or more embodiments of the invention are best summarized by the claims that follow below.

### BRIEF DESCRIPTION OF THE DRAWINGS

The detailed description of embodiments of the disclosure can be better understood when read in conjunction with the drawings enclosed herewith.

FIG. 1 is an exploded perspective rear view of a case for an electronic device;

FIG. 1A is a magnified back side view of a second shell portion of the shell illustrated in FIG. 1;

FIG. 1B is a magnified front side view of the second shell portion illustrated in FIG. 1A;

FIG. 1C is a magnified back side view of an alternate second shell portion for the shell illustrated in FIG. 1;

FIG. 1D is a magnified side view of an edge of the first shell portion and the second shell portion illustrating a fastener to fasten the shell portions together;

FIG. 1E is a magnified side view of an edge of the first shell portion and the second shell portion illustrating an alternate fastener to fasten the shell portions together;

FIG. 2 is a front view of a handle for a case for an electronic device;

FIG. 2A is a back view of a portion of the handle;

FIG. 2B is a back view of a portion of an alternate handle;

FIG. 3 is a side view of a handle for a case for an electronic device;

FIG. 3A is a side view of a handle with brackets pivoted away from each other;

FIG. 3B is a perspective view of a handle with spring loaded brackets pivoted away by a spring;

FIG. 3C is a sectional view of the retention bracket released from the handle bracket;

FIG. 3D is a plan view of a handle with a cutaway view illustrating the compression of springs in the retention device of the retention bracket;

FIG. 4 is a perspective front view of a case for an electronic device;

FIG. 4A is a magnified view of a portion of the first shell portion with a button opening;

FIGS. 4B-4E are magnified views of a portion of the first shell portion with a button extension;

FIG. 5 is a sectional view of a case for an electronic device, wherein the case is in an open orientation;

FIG. 5A is a sectional exploded view of an alternate case for an electronic device in an open orientation;

FIG. 6 is a sectional view of a case for an electronic device, wherein the case is in a closed orientation with the electronic device enclosed therein;

FIG. 7 is a perspective front view of a case for an electronic device;

FIG. 8 is a perspective rear view of a case for an electronic device;

FIG. 9 is a perspective front view of a case for an electronic device;

FIG. 10 is a perspective top view of a case for an electronic device;

FIG. 11 illustrates a perspective exploded view of a case for an electronic device;

FIG. 12A illustrates a top perspective view of a case for an electronic device that receives a magnetically coupled cover;

FIG. 12B illustrates a top perspective view of an alternate case for an electronic device that receives a magnetically coupled cover; and

FIG. 12C is a magnified sectional view of the shell of FIG. 12B engaging the magnetically coupled cover;

The embodiments set forth in the drawings are illustrative in nature and not intended to be limiting of the subject matter defined by the claims. Moreover, individual features of the drawings and examples will be more fully apparent and understood in view of the detailed description.

### DETAILED DESCRIPTION

Embodiments of the invention disclosed herein are directed to cases for electronic devices. The embodiments of cases disclosed herein may include a handle coupled to a shell that at least partially surrounds the electronic device. The handle allows a user to securely hold the case, and therefore the electronic device, while interacting with the electronic device. The handle is adapted to rotate about the shell such that a user can reposition the electronic device through 360 degrees of rotation. Further, the handle includes a support end that may extend away from the shell. The support end may be deployed by a user to support the case in a free-standing position in either a landscape orientation or a portrait orientation.

As used herein, “landscape orientation” and “portrait orientation” refer to the rotational orientation of an electronic device that has a rectangular display. Specifically, “landscape orientation” refers to viewing the electronic device such that the longer side of the rectangular display is approximately horizontal, while the shorter side of the rectangular display is approximately vertical. In contrast, “portrait orientation” refers to viewing the electronic device such that the longer side of the rectangular display is approximately vertical, while the shorter side of the rectangular display is approximately horizontal.

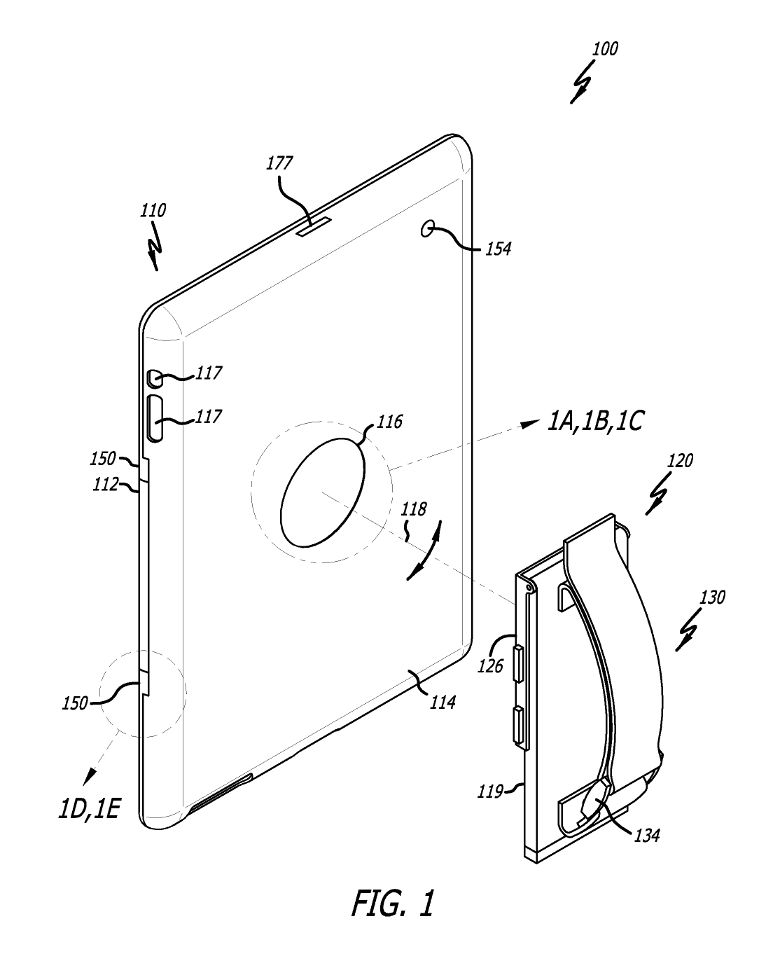

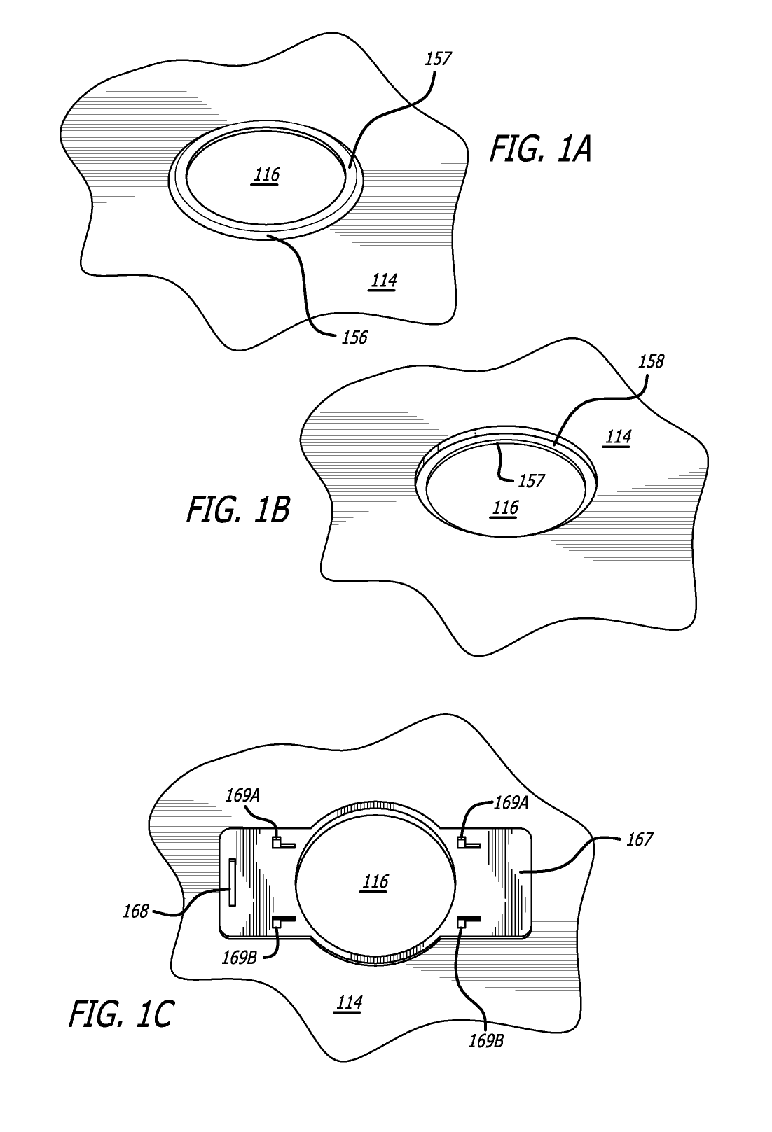

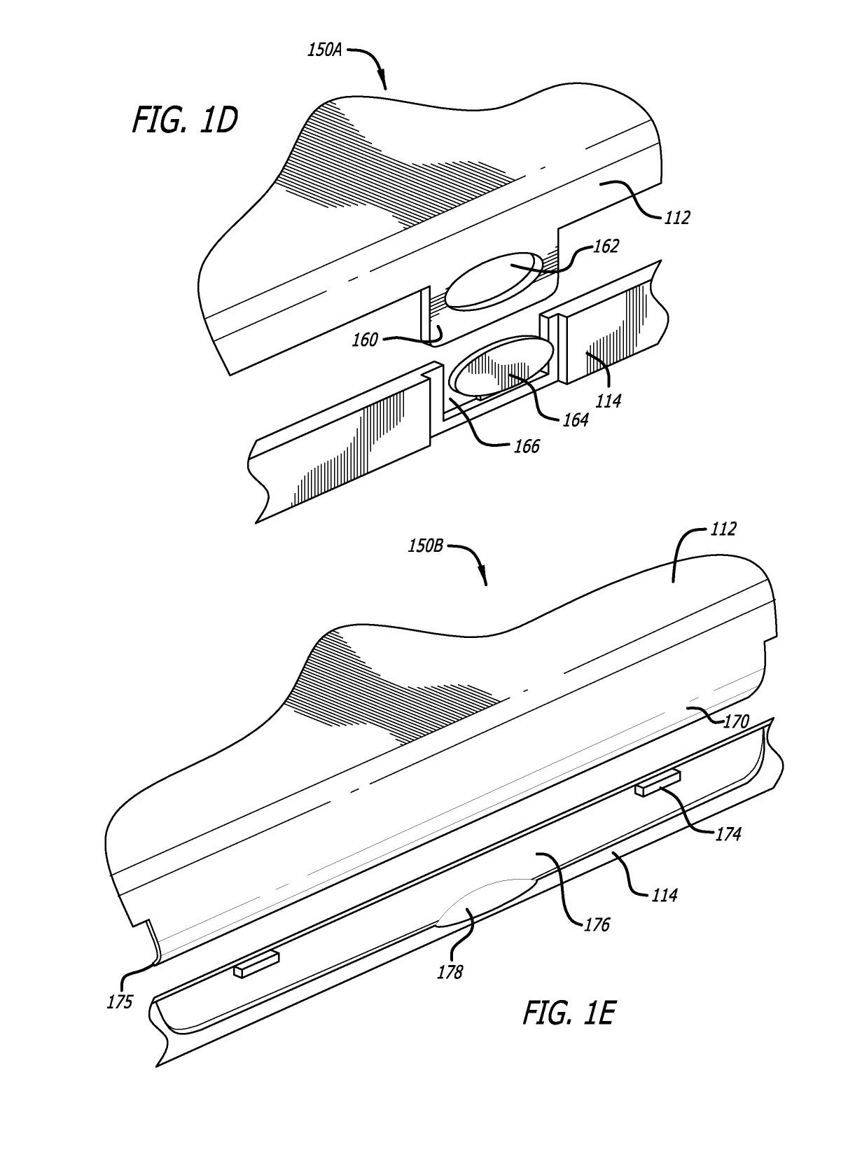

Referring now to FIG. 1, aspects of a case 100 for an electronic device 90 are illustrated according to one embodiment of the invention. The case 100 includes a shell 110 and a handle (rotatable handle) 120. The shell 110 includes a first shell portion (half) 112 and a second shell portion (half) 114.

A circular opening 116 is disposed along the second shell portion 114 of the shell 110. The circular opening 116 defines an axis of rotation 118 along the center of the circular opening 116. Although opening 116 is described and shown as circular in shape, it is understood that opening 116 may comprise any shape that allows the handle to pivot or rotate with respect to the shell 110 along the rotational axis 118. The second shell portion 114 of the shell 110 may further include a first camera opening 154 to align with an optical axis of a first camera of an electronic device to allow images to be captured in a first direction. The shell 110 may also include one or more control openings 117 formed along its edges by portions of the opening in each edge of the first shell portion 112 and the second shell portion 114.

The handle 120 is secured to the circular opening 116 along the second shell portion 114 such that the handle 120 is free to rotate 360 degrees about the axis of rotation 118 relative to the shell 110. Embodiments of the handle 120 may include a grip handle, an elastic securing strap for either hand or for securing the electronic device 90 within the shell 110 to another surface, a gloved handle, or any other fastener that operates to removably attach the shell 110 to an anchoring surface. In one embodiment, the handle 120 may include a retention bracket 126 coupled to a handle bracket 119, and a strap assembly 130 coupled to the handle bracket 119 as illustrated. The retention bracket 126 is pivotally coupled to the handle bracket 119 at one end and near the opposite end the retention bracket 126 is detachably coupled to the handle bracket 119 so as to allow it to selectively pivot away from the handle bracket.

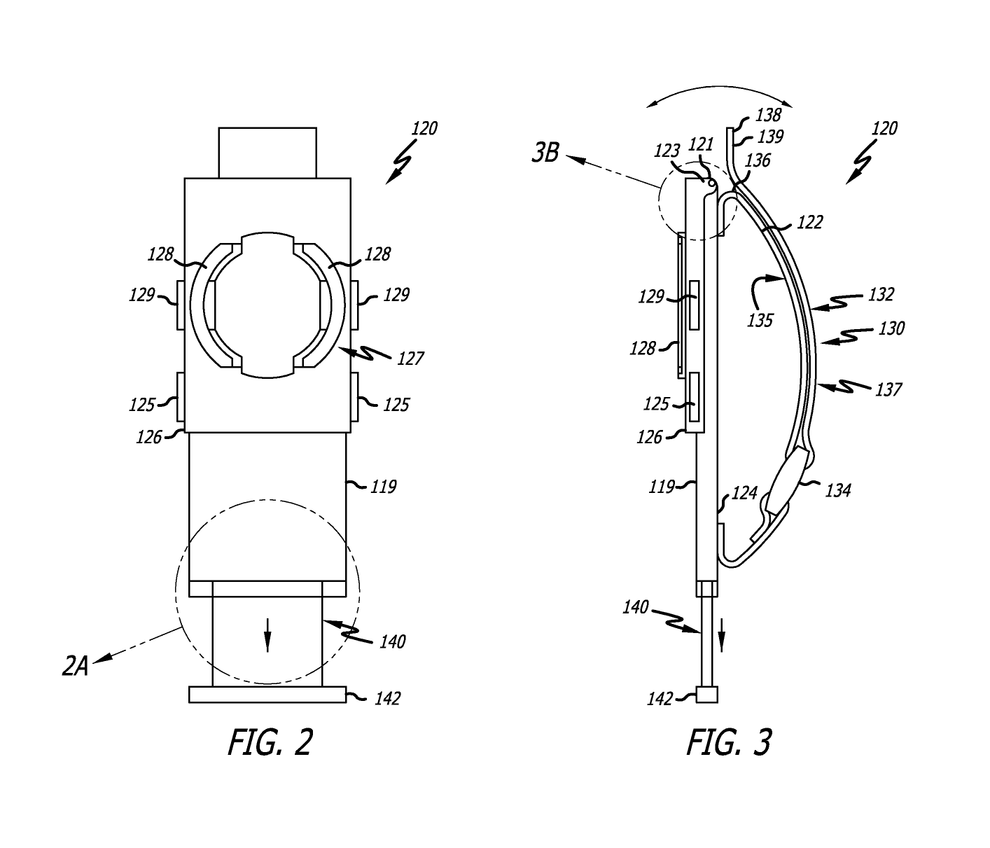

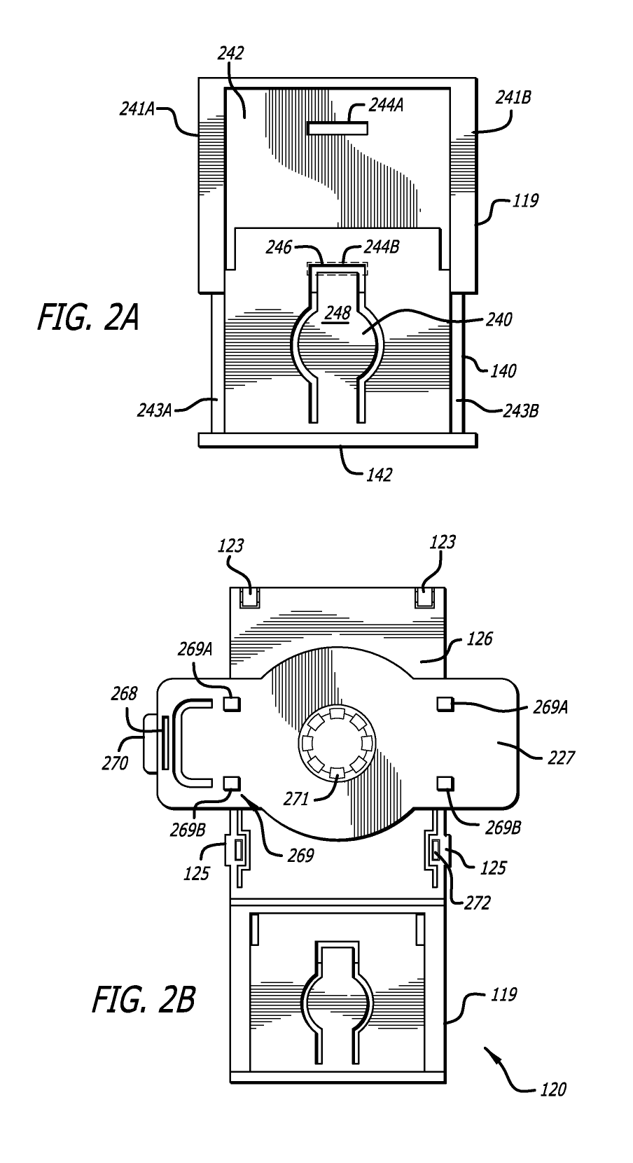

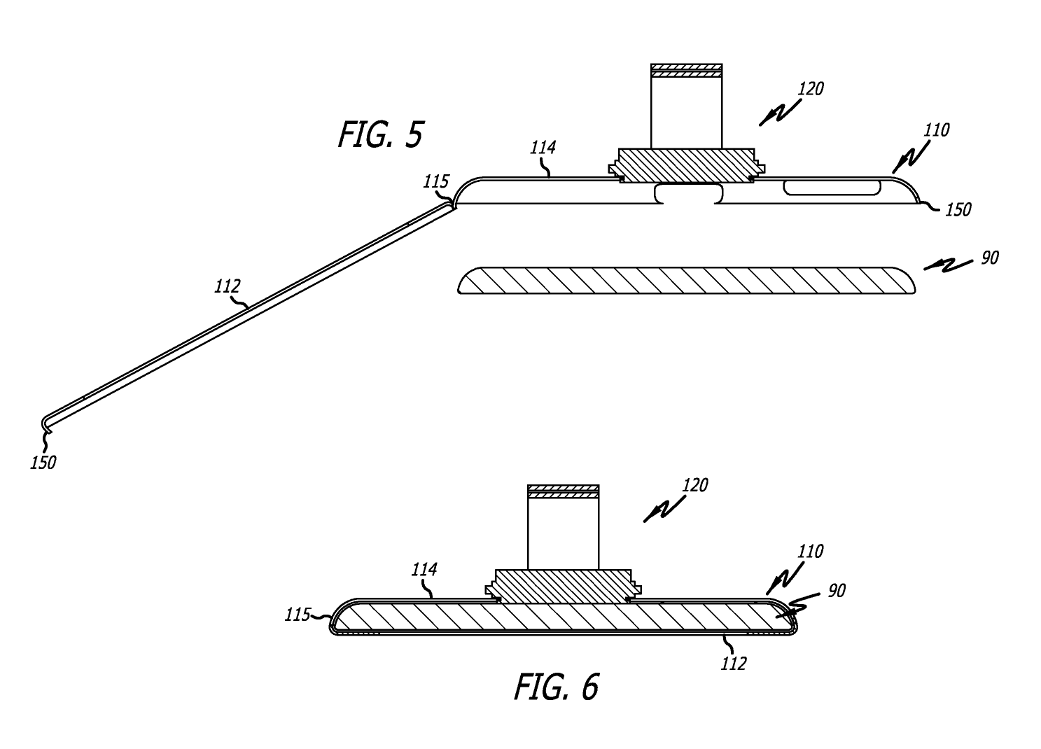

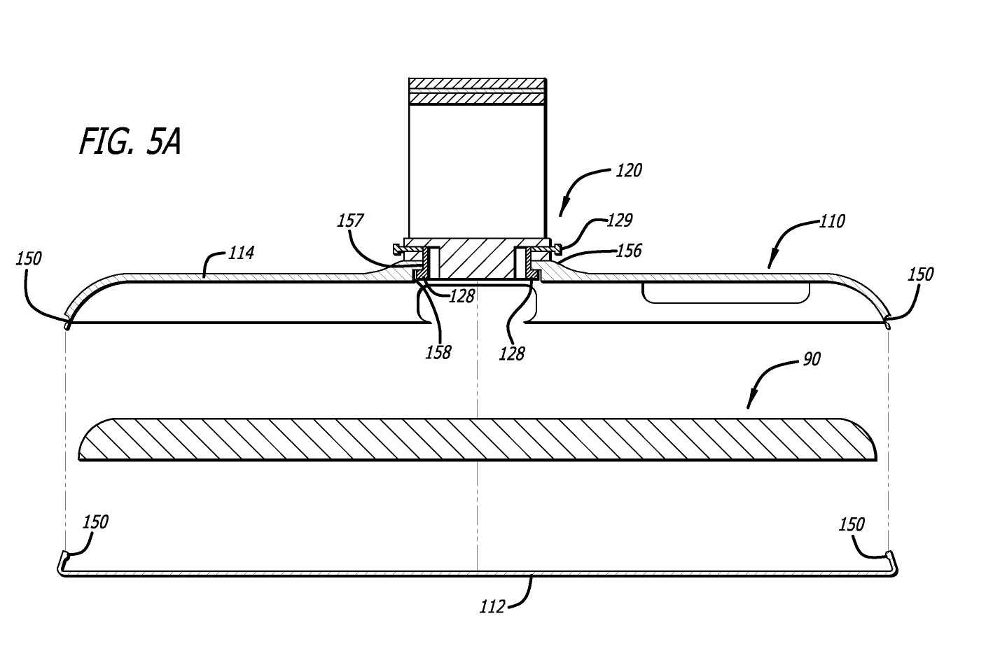

FIG. 1A illustrates a magnified portion of the second shell portion 114 in accordance with one embodiment of the invention. (see also FIG. 5A for cross-section detail and FIG. 2 for retention element detail) The second shell portion includes a raised convex ring 156 about the opening 116 to reinforce the back of the shell. Near the opening 116, there may further be a reinforced portion (ring) 157 to which retention keys 128 of a retention element 127 in the retention bracket 126 may detachably couple.

FIG. 1B illustrates an opposite view (front side) of the magnified portion of the second shell portion 114. (see FIG. 5A for cross-section detail and FIG. 2 for retention element detail) In this view, a larger diameter circle opening 158 is provided in the second shell portion 114 above the opening 116 to receive the retention keys 128 of the retention element 127. Thus, the rotatable handle when engaged into the opening 116 can freely rotate without interference from the back of an electronic device resting against the inner surface of the second shell portion.

Referring now to FIG. 1C, a magnified portion of the second shell portion 114 is illustrated in accordance with another embodiment of the invention. The second shell portion 114 includes a reinforced portion (rectangle) 167 around the opening 116. The reinforced portion 167 has two pairs of opposing sliding key slots 169A-169B on opposite sides of the circular opening 116. The two pairs of opposing sliding key slots 169A-169B are shaped like an L on one side while shaped like a rectangle on the opposite side. The key slots 169A-169B are adapted to slidingly receive two pairs of opposing hooks (see hooks 269A-269B illustrated in FIG. 2B) of the retention element 227 of the handle 120. The reinforced portion 167 further has a groove 168 on one side of the circular opening 116. The groove 168 is adapted to slidingly receive a latch 268 of the retention element 227 and hold the handle 120 coupled to the shell 110.

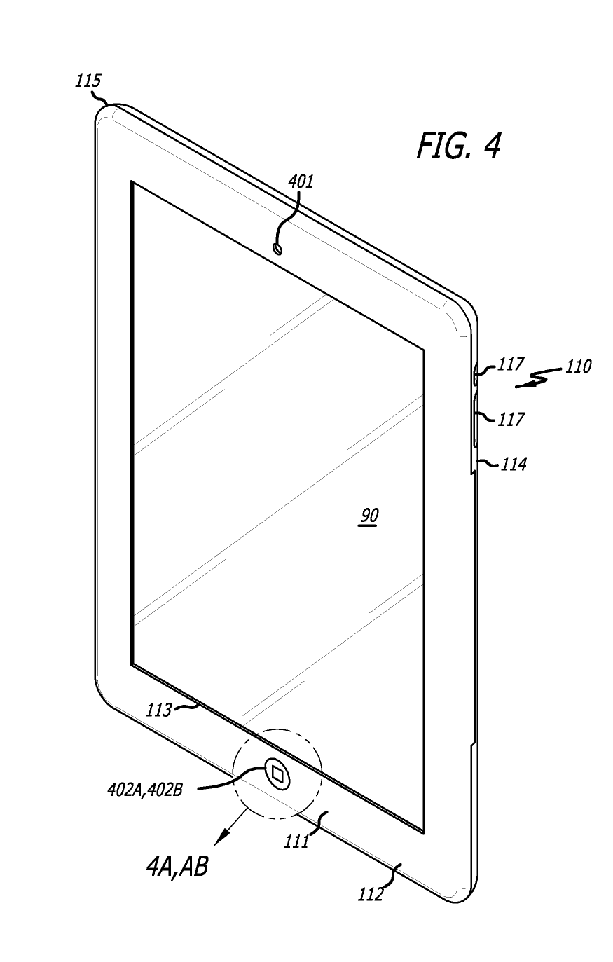

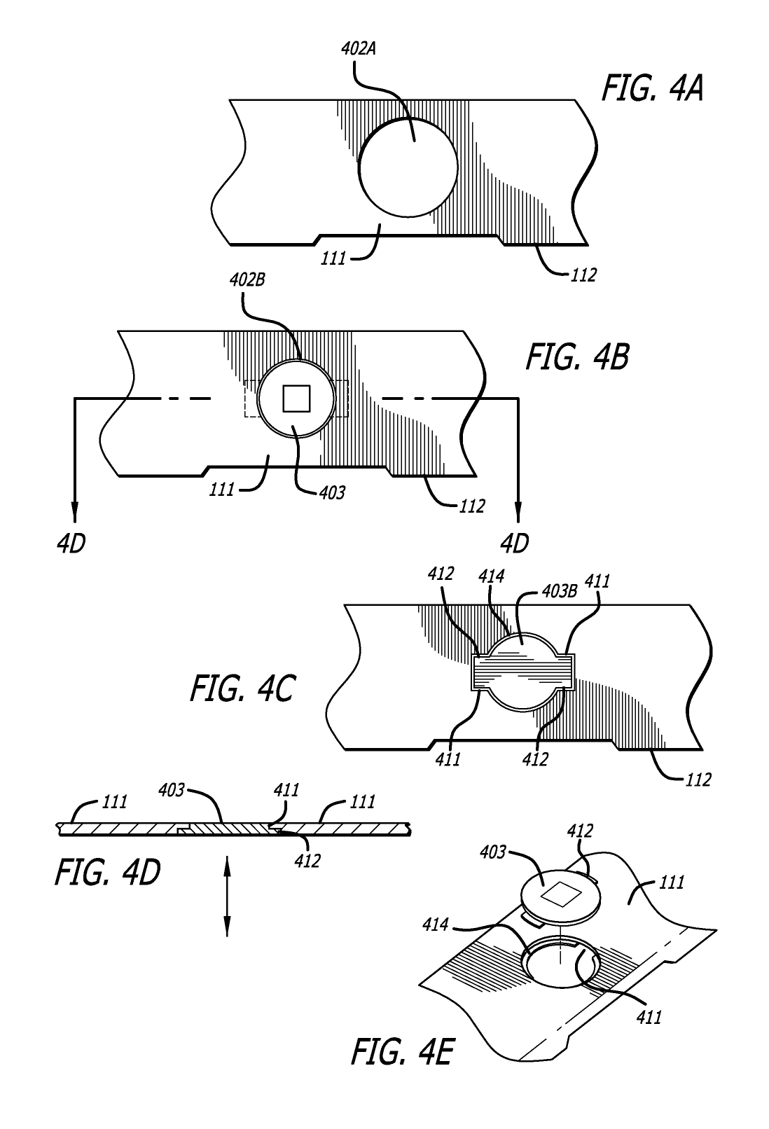

Referring now back to FIG. 1, the shell 110 further includes one or more fasteners 150 along one or more edges to couple the first shell portion 112 and the second shell portion 114 together. The shell may include one or more hinges 115 (see FIGS. 4 and 5) along an edge to pivotally couple the first shell portion 112 and the second shell portion 114 together.

Referring now to FIG. 1D, a magnified view of a fastener 150A is illustrated. The fastener 150A includes a catch (clasp) 160 with an oval opening 162 in one shell portion to engage an oval latch (locking snap) 164 in the opposite shell portion. In one embodiment, the catch 162 extends out from the edge of the first shell portion 112 while the oval latch 164 is positioned within a recess 166 in the edge of the second shell portion 114. Alternatively, the catch 162 may extend out from the edge of the second shell portion 114 while the oval latch 164 is positioned within a recess 166 in an edge of the first shell portion 112.

To close the case and couple the first shell portion and second shell portion together, the edges of each are squeezed together to momentarily deflect the catch 160 over the latch 164 so that the opening 162 surrounds the latch 164. To open the case and decouple the fasteners, the catch 160 is pulled out so that the opening 162 is clear of the latch 164 and the shell portions are pulled apart.

Referring now to FIG. 1E, a magnified view of an alternate fastener 150B is illustrated. The fastener 150B includes one or more latches 174 near an edge of one shell portion formed within a recess portion 176 that is adapted to engage a curved catch 175 in the opposite shell portion 112. The curved catch 175 reaches into the indentation portion 176 to engage each of the one or more latches 174. The recess portion 176 in the edge of the shell further includes a finger release indentation 178 that allows a user to insert a finger and pry up on the catch 175 to disengage it from the latches 174 to release the fastener. In one embodiment, the catch 175 is in an edge of the first shell portion 112 while the latches 174 extend out from the edge of the second shell portion 114. Alternatively, the catch 175 may extend out from the edge of the second shell portion 114 while the latches 174 are positioned along an edge of the first shell portion 112.

To close the case and couple the first shell portion and second shell portion together, the edges of each are squeezed together to momentarily deflect the latch 170 over edge so that the hook 174 can couple into the catch 175. To open the case and decouple the fasteners, the latch 170 is pulled out so that the hook 174 is pulled out clear of the opening of the catch 175 so that the shell portions can be pulled apart.

Referring now to FIG. 2, the handle 120 includes a retention element 127 that is a part of the retention bracket 126 that secures the handle 120 to the circular opening 116 of the shell 110. The retention element 127 includes at least one retention key 128 that a user may actuate as to engage and/or disengage the retention element 127 with the circular opening 116. In the embodiment depicted in FIG. 2, the retention keys 128 are formed from semi-circular portions that extend from the handle bracket 119. The retention keys 128 may be elastically biased outwards by, for example, springs or compliant supports, such that the retention keys 128 press outwards to engage the circular opening 116. The retention keys 128 may include retention actuation pads 129 along the outside of the retention keys 128, which enable a user to depress the retention keys 128 as to disengage the retention element 127 from the circular opening 116 when the handle 120 is coupled to the shell 110.

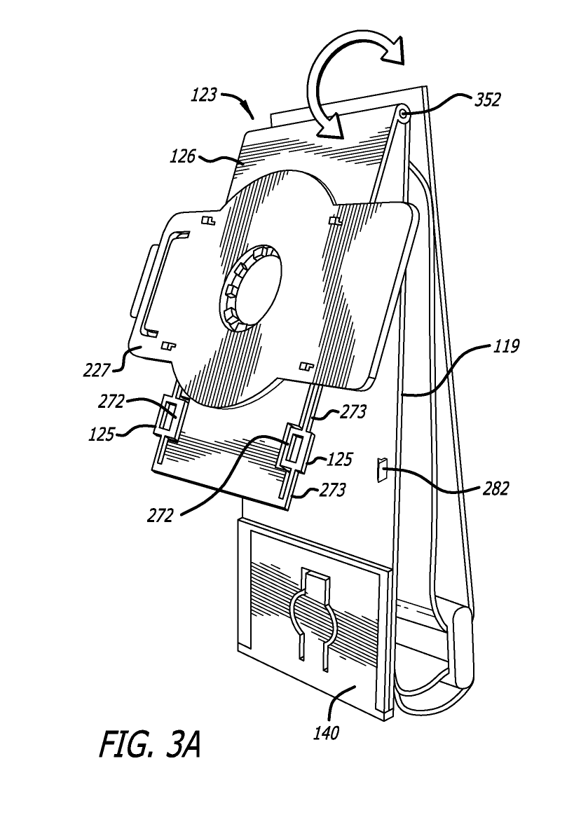

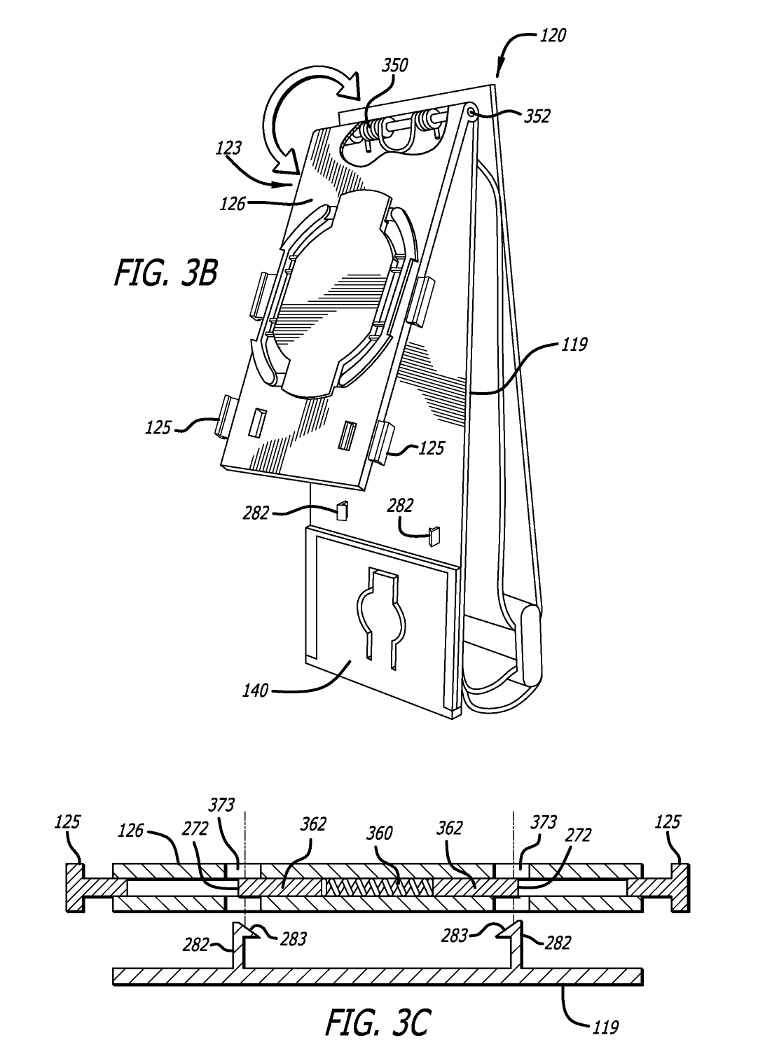

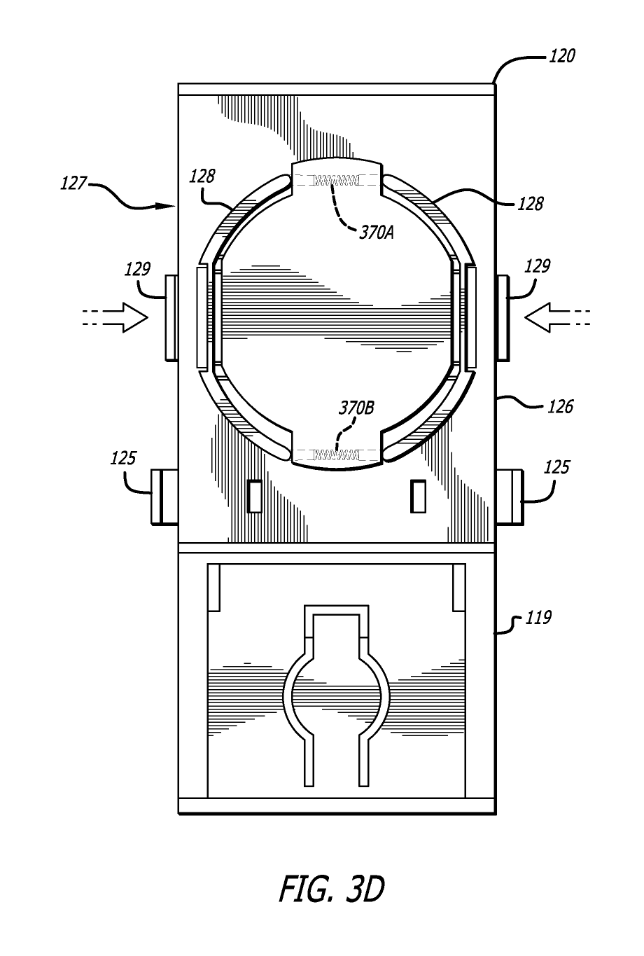

The handle 120 depicted in FIG. 2 also includes a set of stand actuation pads 125. The stand actuation pads 125 selectively engage the handle bracket 119 with the retention element 127. The stand actuation pads 125 may be actuation by a user to unlock the handle bracket 119 from the retention element 127, thereby allowing the handle bracket 119 to be pivoted about the handle hinge 123 as shown in FIG. 3. The handle 120 further includes a slideable support end 140 that slides and extends out from one end of the handle bracket 119.

The support end 140 includes a contact surface 142 that includes a high friction material. The high friction material may have a static coefficient of friction that is greater than 0.4. Examples of such materials that exhibit this property include silicone rubber and acrylic rubber. The support end 140 may also extend along the handle bracket 119, thereby increasing the length from the shell 110 to the contact surface 142 measured along from the handle 120.

Referring momentarily to FIG. 2A, the slideable support end 140 is illustrated extending out from the handle bracket 119 sliding along a surface 242 of the handle bracket 119. The slideable support end 140 includes a pair of rails 243A-243B that slide and are guided along a respective pair of guide rails 241A-241B coupled to the surface 242. The slideable support end 140 includes a flexible tongue portion 240 with a latch 246 near one end and a finger tab 248 near a middle portion. The latch 246 engages a shallow groove 244A in the surface 242 to hold it in a closed position within the handle bracket 119. The slideable support end 140 can be pulled on and slid out to disengage the latch 246 from the groove 244A. The slideable support end 140 further slides out so that the latch 246 engages a deep groove 244B in the handle bracket 119 to hold it in an extended position extending out from the end of the bracket 119.

Sliding the slideable support end 140 to alter its extension from the bracket and overall length of the handle can adjust the angle of shell 110 to stand upon a surface at different angles so that a display of an electronic device can be viewed at different angles by a user. To disengage the latch 246 from the deep groove 244B in the open or extended position, a user presses up on the finger tab 248 from below. The user then pushes in on the slideable support end 140 to slide it towards the closed position.

Referring now to FIG. 2B, a retention element 227 is illustrated rotatably coupled to the retention bracket 126 of the handle 120. The retention bracket 126 includes a plurality of hooks 271 spaced apart about a circle to coupled into a circle opening 272 in the retention element 227. The retention bracket 126 further includes moveable catch openings 272 that are adapted to couple to hooks 282 of the handle bracket 119. The catch openings 272 are actuated by push buttons 125 to detachably couple an end of retention bracket 126 to the handle bracket.

The retention element 227 includes two pairs of opposing hooks 269A-269B on opposite sides of the opening 272 to detachably couple the handle to the shell 110 as further described herein. The retention element 227 further includes a latch protrusion 268 to engage a groove 168 in the second shell portion 114. The retention element 227 further includes a pull tab 270 to disengage the latch protrusion 268 from the groove so that the retention element 227 can slide and to disengage the hooks 269A-296B from the keyholes 169A-169B in the second shell portion 114.

The handle includes one or more hinges 123 to pivot the handle bracket 119 away from the retention bracket 126 and retention element 127,227. The handle may further include one or more springs to form a spring loaded device such that the handle bracket 119 is forced away from the retention bracket 126 to a maximum pivot angle (see wound torsional spring 350 around pivot pin 352 of the hinge 123 illustrated in FIG. 3B).

FIG. 3 illustrates the handle 120 with the handle bracket 199 coupled to the retention bracket 126. The handle bracket 199 is pivotally coupled to the retention bracket 126 at a first (top) end by one or more hinges 123. The handle bracket 199 is detachably coupled to a second (bottom) end of the retention bracket 126. Hooks 282 (see FIG. 3A) of the handle bracket 119 are engaged to catches 272 (see FIG. 2B) of the retention bracket 126. Pressing the buttons 125 disengages the catches 272 from the hooks 282 so that the handle bracket 199 can then be pivoted away from the retention bracket 126 at the second end.

FIG. 3A illustrates the handle 120 with the handle bracket 199 pivoted away from the second (bottom) end of the retention bracket 126. The handle bracket 199 remains pivotally coupled to the retention bracket 126 at the first end.

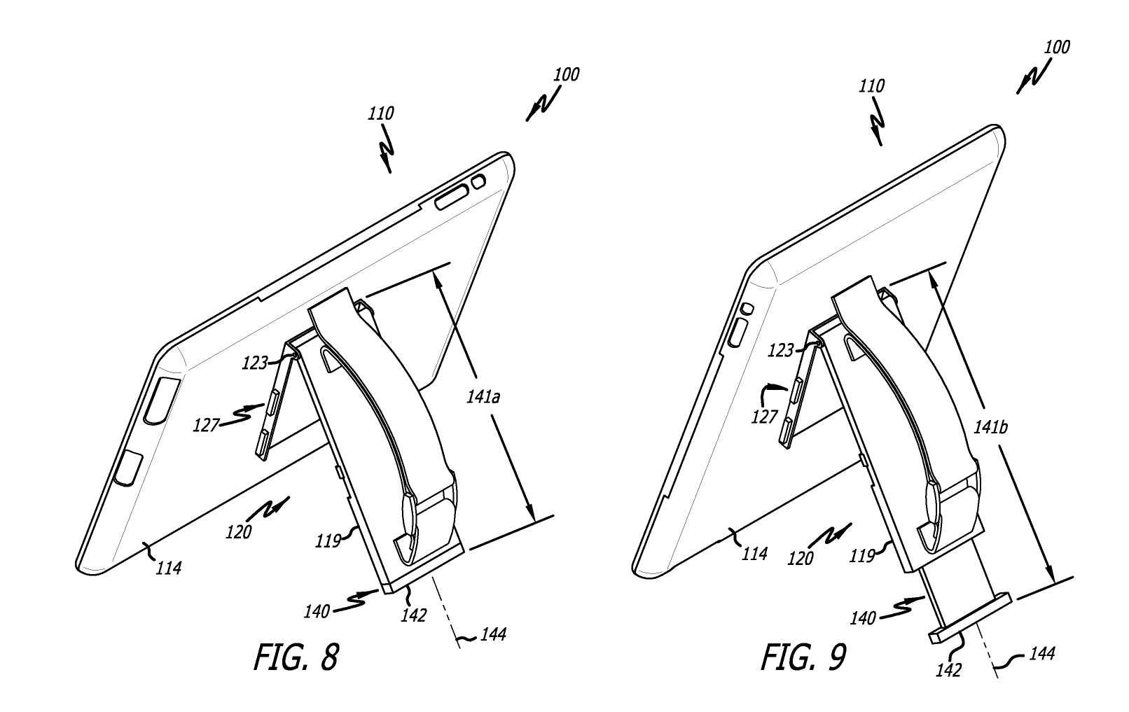

With the handle bracket 119 pivoted away from the retention element 127, and therefore the shell 110, the support end 140 and a portion of the second shell portion 114 of the shell 110 may be placed into contact with a surface to maintain the case 100 and the enclosed electronic device 90 in a free-standing position at different angles, such as illustrated in FIGS. 8 and 9.

Referring now to FIG. 3B, the handle 120 further includes one or more torsional springs 350 (see cutaway illustrated in FIG. 3B) around a pivot pin 352 of the hinge 123. One or both ends of one or more torsional springs 350 may couple to the handle bracket 119 while another portion of the spring couples to the retention bracket 126. In the illustration, both ends to a single torsional spring couple to the handle bracket 119 while a middle loop couples to the single torsional spring couples to the retention bracket 126. Alternatively, one or both ends of one or more torsional springs 350 may couple to the retention bracket 126 while another portion of the spring couples to the handle bracket 119. The force of the one or more torsional springs 350 spring loads the handle bracket 119 so that it is forced away from the retention bracket 126 to a maximum pivot angle upon pressing the buttons 125 to disengage the catches 272 from the hooks 282. The pivot pin 352 of the hinge pivotally couples the handle bracket 119 to the retention bracket 126. The handle bracket 119 pivots around the retention bracket 126 at the pivot pin 352.

Referring momentarily back to FIG. 3A, the catches 272 and buttons 125 are coupled to resilient arms 273 of the bracket 126 so that they can be depressed into an open position to release the handle bracket from the retention bracket in accordance with one embodiment. The buttons 25 can then be released so that the catches 272 are returned to a closed position by the resilient arms 273 so they are ready to catch the hooks 282.

Referring now to FIG. 3C, a cross section of the retention bracket 126 released from the handle bracket 119 is illustrated in accordance an embodiment of the invention. The buttons 125 and catches 272 are part of a pair of sliding release mechanisms 362 coupled to a compression spring 360 within the retention bracket 126. When the buttons are pressed together, the pair of sliding release mechanisms 362 compress the spring 360 to move the catches 272 relative to openings 373 in the retention bracket. With the openings 373 clear of the catches 272, the opposing hooks 282 of the handle bracket can pass through to release the lower coupling between the handle bracket and the retention bracket. With the buttons released, the spring 360 forces the pair of sliding release mechanisms outward so that the catches 272 are positioned within the openings 373.

Upon closing the brackets together, the opposing hooks 382 include a ramp portion 283 that can mate with the catches 272 to slide the pair of sliding release mechanisms 362 and compress the spring 360 to move the catches 272 relative to openings 373. After passing the end of the ramp 283 with the catches, the spring 360 forces the pair of sliding release mechanisms outward so that the catches 272 are positioned within the openings 373 behind the hooks to couple the handle bracket and the retention bracket together.

Referring now to FIG. 3D, a view of the retention keys 128 in a depressed state is illustrated. To couple the handle 120 to the shell, actuation pads (buttons) 129 coupled to the retention keys 128 are squeezed together. The retention keys slide within the bracket 126 and compress a pair of coiled springs 370A-370B between them. This reduces the diameter distance separating the arc-like shape hook of the keys 128 so that they can be inserted within the opening 116 of the second shell portion of the shell. Upon releasing the actuation pads (buttons) 129 with the keys in the opening, the pair of coil springs 370A-370B push on and slide out the keys 128 and actuation pads (buttons) 129. The arc shape edge of each of the keys 128 expands outward to engage the reinforced edge 157 of the opening 116 (see FIG. 5A) thereby increasing the diameter distance of separation. The arc-like shape hook of the keys 128 rotate within the recessed opening 128 and allow the handle 120 to rotate within the opening 116 with respect to the shell. To detach the handle, the actuation pads (buttons) 129 may be squeezed together as shown in FIG. 3D. With it being attachable and detachable in this manner, the handle 120 can be rotatably coupled to and decoupled from the shell 110.

Referring now to back FIG. 3, the handle 120 also includes an extendable strap assembly 130. The extendible strap assembly 130, together with the handle bracket 119, creates an internal envelope 122 into which a user can insert his or her hand. The extendible strap assembly 130 increases and decreases in length to provide adjustment to the size of the internal envelope 122 such that the internal envelope 122 can be adjusted to accommodate hands of differing sizes.

The extendible strap assembly 130 includes a tongue (strap) 132 attached to a first portion 121 of the handle bracket 119 and a cinch ring 134 coupled to a second portion 124 of the handle bracket 119. The tongue (strap) 132 includes a first tongue section 135 and a second tongue section 137. The first tongue section 135 includes one of a hook material or a loop material 136. The second tongue section 137 includes one of a loop material or a hook material 138 adapted to respectively engage the hook material or loop material 136 of the first tongue section 135. The second tongue portion 137 of the tongue (strap) passes through the cinch ring 134 and is doubled back wrapping over the cinch ring and onto the first tongue portion 135, where the adjacent hook material and loop material 136, 138 may be affixed to one another.

The size of the internal envelope 122 can be adjusted by a user by detaching the second tongue portion 137 from the first tongue portion 135, repositioning the tongue (strap) 132 within the cinch ring 134, and affixing the second tongue portion 137 to the first tongue portion 135 at a different position. To ease adjustment of the extendable strap assembly and the size of the envelope, an end of the tongue (strap) 132 includes a pull tab 139 without hook material or loop material so that it can be readily grabbed and release the end of the strap from affixing to itself

The extendable strap assembly can be opened by a user pulling on the pull tab 139 and letting the tongue (strap) 132 out through the cinch ring 134 to increase the size of the envelope 122 and readily receive the hand of a user. With the user's hand in the envelope, the extendable strap assembly can be closed by the user by pulling on the pull tab and pulling on the tongue (strap) 132 through the cinch ring 134 to decrease the size of the envelope 122 to tightly couple the rotatable handle to the hand of the user.

Referring now to FIG. 4, the shell 110 of the case 100 includes a rectangular display opening 113 that passes through the first shell portion 112. The display opening 113 may include a transparent film that provides protection to at least one of the surfaces of the electronic device 90. Alternately, the display opening 113 may include an opening that allows unconstrained access to the electronic device 90. The display opening 113 allows a user to view the screen of the electronic device 90, and for electronic devices 90 that incorporate touch screens, the display opening 113 allows the user to control the electronic device 90 through contact with the touch screen. The shell 110 may also include one or more control openings 117. The control openings 117 are aligned with the additional control features of the electronic device 90, for example, a volume rocker switch, a lock button, a camera, and a charging port. The control openings 117 provide access to such control features without having to remove the electronic device 90 from the shell 110.

The first shell portion 112 of the shell 110 may further include a camera opening 401 to align with an optical axis of a second camera of an electronic device to allow images to be captured in a second direction different from images captured in a first direction by a first camera. The camera opening 401 is in a bezel 111 of the first shell portion 112 of the shell 110.

One embodiment of the case 100 may include a shell 110 that includes a clam shell design, where the electronic device 90 is secured within a shell 110 that articulates between an opened position and a closed position, as depicted in FIGS. 4-6. In this embodiment, the first shell portion 112 is connected to the second shell portion 114 through a hinge portion 115. In this embodiment, the hinge portion 115 is integrated into both the first shell portion 112 and the second shell portion 114; however, other embodiments may include a discrete hinge attached to both the first and second shell portions 112, 114. One or more fasteners 150, described herein may also be integrated into the first shell portion 112 and the second shell portion 114 to couple them closed together in the closed position.

In the embodiment, depicted in FIGS. 4-6, the first shell portion 112 includes a bezel 111 and a display opening 113. The bezel 111 is dimensionally smaller than the overall dimensions of the electronic device 90 such that the shell 110 at least partially surrounds a generally cuboid electronic device 90 along six faces. The display opening 113 passes through the first shell portion 112 and through the bezel 111. The display opening 113 is sized such that a user may continue to operate and interact with the electronic device 90 through the use of the user interface of the electronic device 90.

Referring now to FIG. 4A, the first shell portion 112 in one embodiment includes one or more button openings 402A in the bezel 111. The one or more openings 402A in the bezel 111 are aligned over one or more buttons or switches of the electronic device 90. The one or openings 402A in the bezel 111 allow a user's finger to pass through the bezel to touch and operate the one or more control buttons or switches of the electronic device.

Referring now to FIGS. 4B-4E, the first shell portion 112 in another embodiment includes one or more button extensions 403 within one or more openings 402B in the bezel 111. The one or more button extensions 403 in the bezel 111 are aligned over one or more buttons or switches of the electronic device 90. For example, in the case of APPLE's IPAD electronic device, a button extension 403 may be aligned over and select the home control button when the button extension is pressed.

As illustrated by the double-headed arrow shown in cross section of FIG. 4D, the one or more button extensions 403 move back and forth in the bezel 111 to extend the force of a user's finger through the shell to operate one or more buttons or switches of an electronic device. The button extension 403 remains loosely coupled to the shell so that it can move up and down to depress and release a control button. The button extension 403 is loosely coupled to the shell by one or more retaining devices 411.

FIG. 4C illustrates a back side 403B of the button extension 403 that can couple to a control button of an electronic device. As shown in FIG. 4E, the opening 402B located in the bezel on a front side of the first shell portion 112 extends through to an opening 414 in a back side of the first shell portion. In one embodiment, a pair of retaining devices (slots) 411 are on opposite sides of the opening 402B,414 are used to retain tabs 412 of the button extension 403, but allow the button extension 303 to move and select the control buttons of the electronic device.

As depicted in FIG. 5, the shell 110 may be placed in an open position such that the first shell portion 112 does not enclose six faces of a generally cuboid electronic device 90. The electronic device 90 may be nestled within the second shell portion 114 and the first shell portion 112 is articulated about the hinge portion 115 such that the first shell portion 112 is aligned with the second shell portion 114. The first shell portion 112 may then be coupled to the second shell portion 114 by one or more fasteners 150, such as those described herein, to secure the electronic device 90 within the shell 110.

FIG. 6 illustrates a cross section view of the first shell portion 112 and the second shell portion 114 are detachably coupled together by the hinge and the one or more fasteners 150 to form the shell 110. The electronic device 90 is secured with the shell 110. The handle 120 is rotatably coupled to the shell 110.

Referring now to FIG. 5A, a shell 110 with one or more fasteners 150 along opposing edges is illustrated. The shell 110′ does not employ a hinge 115 along any edge. A first shell portion 112 and a second shell portion 114 are used to sandwich the electronic device 90 there-between. The one or more fasteners 150 along opposing edges of the shell may be the fasteners 150A,150B described herein with reference to FIGS. 1D and 1E.

Shells 110,110′ may be made from polymers that exhibit high relative strength and stiffness, for example, acrylonitrile butadiene styrene (ABS), polycarbonate, or combinations thereof. Shells 110.110′ made with these materials may exhibit rigidity, which may protect the enclosed electronic device 90 from damage due to abrasion, impact, and/or compressive loading.

To increase the tactile feel of a shell, the external surfaces of the shell may be coated with a polymeric compound that exhibits reduced hardness as compared with the shell material. Such coatings may provide a user with a “rubberized” feel to the shell as to assist the user's grip on the shell. Such tactile polymeric compound coatings that may be used to increase the tactile feel are, for example, elastomers, silicone rubbers, rubber, or rubberized materials.

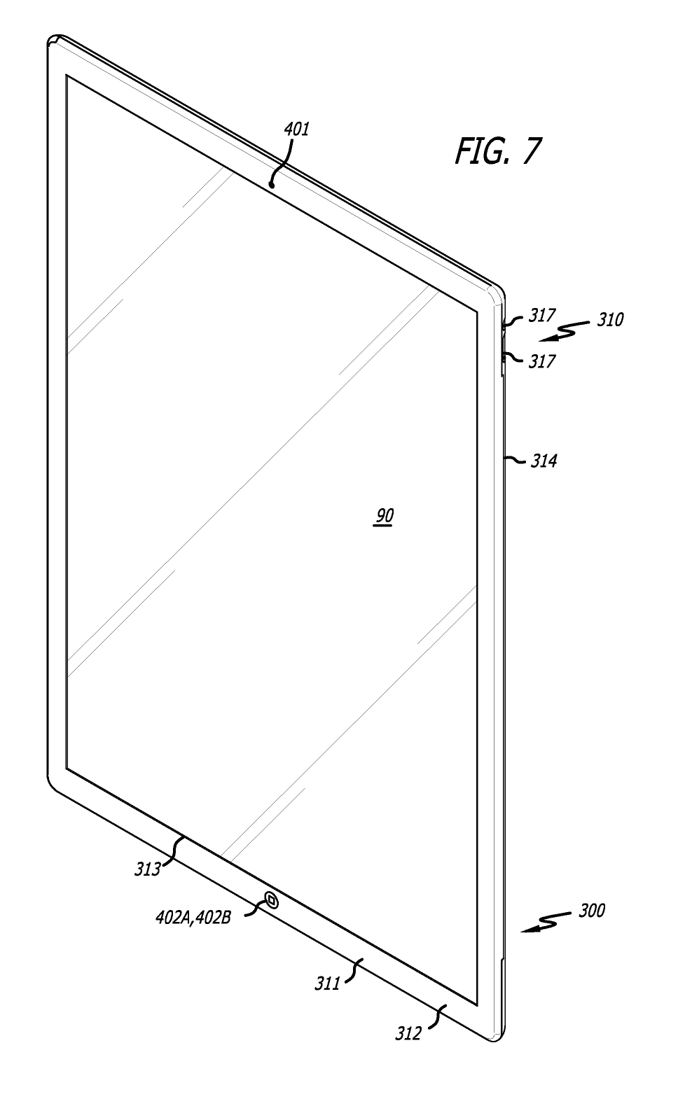

Referring now to FIG. 7, a shell 310 is illustrated coupled around the electronic device 90. In this alternate embodiment of the shell of the case 100, the first shell portion 312 and the second shell portion 314 are integrated with one another to form the integral shell 310. Similar to the embodiment discussed in regard to FIGS. 4-6, the display opening 313 passes through the bezel 311, which is positioned along the first shell portion 312. The electronic device 90 is inserted into the shell 310 by elastically deforming the bezel 311 around the electronic device 90. The electronic device 90 is, therefore, inserted between the first shell portion 312 and the second shell portion 314. Shells 310 made according to this embodiment may be made from polymers that exhibit high relative elasticity and tear strength, for example elastomers, silicone rubbers, rubber, or rubberized materials.

The shell 310 may include one or more camera openings 401,154 in the first shell portion 312 and/or the second shell portion 314. The shell 310 may also include a button opening 402A and/or a button opening 402B and button extension 403 in the first shell portion 312. The shell may also include one or more control openings 317 that function similar to the control openings 117 in shell 110. The control openings 317 are aligned with additional control features of the electronic device 90 to provide access to such control features without having to remove the electronic device 90 from the shell.

Cases according to the present disclosure allow a user to reposition an electronic device 90 while maintaining control without having to apply a substantial grasping force to the electronic device 90. This may be beneficial to users who wish to support the electronic device 90 for extended periods of time without having to grasp the case 100. Cases 100 according to the present disclosure may be ergonomically superior to cases where the user must grasp the case directly (e.g., a case without a handle), because cases 100 according to the present disclosure allow a user to support the electronic device 90 using larger muscle groups than the muscles (e.g., smaller muscle groups) used to grasp the case 100 alone. This may allow a user to hold and maneuver the electronic device 90 for longer periods of time as compared with cases where the user must grasp the case 100 directly.

Additionally, cases 100 according to the present disclosure may allow the user to quickly and reliably reposition the electronic device 90 through a variety of orientations, including a portrait orientation and a landscape orientation. Without repositioning his or her hand inside the internal envelope 122 of the handle 120, a user may rotate the shell 110 of the case 100 and thus the electronic device 90 contained therein about the axis of rotation 118. The ability to rotate the shell 110 and the enclosed electronic device 90 may be beneficial for electronic devices 90 that include accelerometers that adjust screen orientation of images being displayed based on position of the device.

Examples of electronic devices 90 that may be received by the cases include, but are not limited to, smartphones (for example, the APPLE iPhone 4®, the DROID INCREDIBLE by HTC®, and the RIM BLACKBERRY STORM 2®); portable music players (for example, the APPLE iPod touch®, the MICROSOFT ZUNE HD®, and the SONY X-SERIES WALKMAN®); and tablet computers (for example, the APPLE iPad 1®, APPLE iPad 2®, the MOTOROLA XOOM®, and the RIM BLACKBERRY PLAYBOOK®). As a user rotates one of these electronic devices 90, accelerometers within the electronic device 90 are used to determine the rotational orientation of the electronic device 90. The electronic devices 90 may change the orientation of the icons and/or images on the screen to display them in a vertical orientation for the user. Therefore, a user of such an electronic device 90 may choose to modify the orientation of the electronic device 90 to modify the screen orientation based on a particular input or output operation of the electronic device 90. For example, a user may prefer to orient the electronic device 90 in a landscape orientation when entering text via a virtual keyboard, while the user may prefer to orient the electronic device 90 in a portrait orientation when viewing an electronic document.

As discussed above, a user may selectively position the handle 120 in one of a closed position or a deployed position. By placing the handle 120 in the deployed position, a user may rest the case 100 against a surface such that the shell 110 and the handle 120 support the case 100 in a free-standing condition, i.e., without additional support, or interaction from the user. When the case 100 and the enclosed electronic device 90 is supported in a free-standing condition, the electronic device 90 is held in a generally upright, or partially reclined, orientation without further intervention from the user. Additionally, because the handle 120 rotates about the axis of rotation 118, the handle 120 can be rotated through a variety of positions, and can be positioned to support the case 100 in a landscape orientation or a portrait orientation, as depicted in FIGS. 8 and 9, respectively. The extendible strap assembly 130 need not be removed from the handle 120 for the handle 120 to function as both a stand and as a hand-hold grip.

As discussed above, the support end 140 may translate along a longitudinal axis 144 of the handle bracket 119 between a stored position and an extended position.

Referring now to FIG. 8, when the handle 120 is in a deployed position and the case 100 is supported in a landscape orientation, the support end 140 may be positioned in a stored position relative to the handle 120 (i.e., not extended along longitudinal axis 144 of the handle 120). The support end 140 and the second shell portion 114 contact a surface to support the case 100 in a partially reclined orientation. In this orientation, the distance 141a from the shell 110 to the support end 140 may be minimized.

Referring now to FIG. 9, the handle 120 may be rotated relative to the shell 110 such that the support end 140 and the second shell portion 114 support the case 100 in a portrait orientation. Because the electronic device 90 itself is rectangular, to maintain the degree of incline as when being supported in the landscape position depicted in FIG. 8, the support end 140 may be extended along longitudinal axis 144 of the handle bracket 119 such that the support end 140 is an increased distance 141b away from the shell 110 when measured along the handle 120.

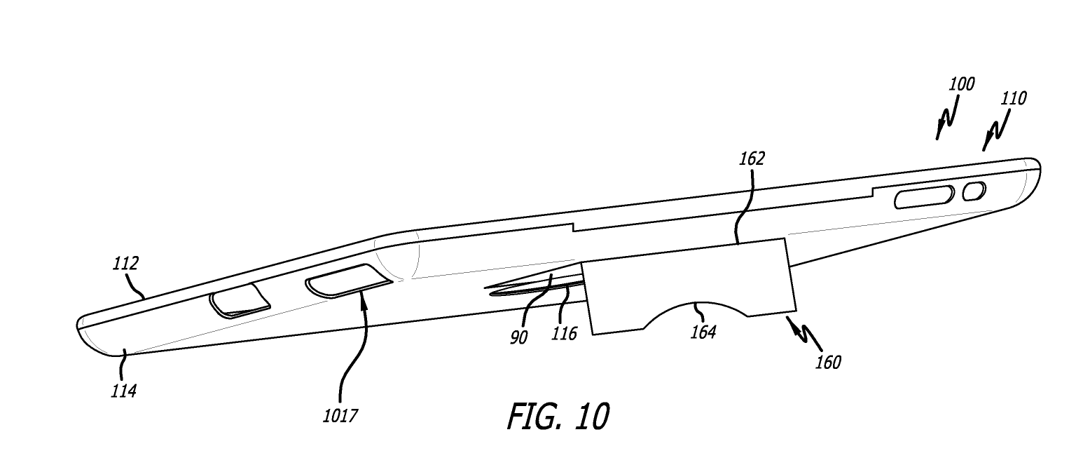

Referring now to FIG. 10, embodiments of the case 100 may include an extendible prop 160. The extendible prop 160 may be stowed along the second shell portion 114 when not in use, such that the extendible prop 160 is embedded in the second shell portion 114. The extendible prop 160 may rotate about a hinge portion 162 between the stowed position and the deployed position. The hinge portion 162 may be integrated into both of the second shell portion 114 and the extendible prop 160. Alternately, the hinge portion 162 may be a discrete element from the second shell portion 114 and the extendible prop 160. One or more of the extendible prop 160 or the second shell portion 114 may include a finger relief 164. The finger relief 164 includes a space between the extendible prop 160 and the second shell portion 114 that allows a user to insert his or her finger between the extendible prop 160 and the second shell portion 114 to grip the extendible prop 160 and rotate it from a stowed position towards a deployed position.

The extendible prop 160 extends from the second shell portion 114 and is positioned to support the case 100, along with the enclosed electronic device 90 in a supine orientation, where the display opening 113 (not shown) faces generally upwards. Supporting the electronic device 90 in such an orientation may provide a position that allows a user to type on the touch screen of the electronic device 90 in comfort.

The shell 110 may further include one or more sound openings aligned with a sound generator or a sound receiver. For example, the shell may include speaker openings 1017 aligned with one or more speakers of the electronic device so that sound may more readily pass through the case 100 to the ears of a user. The speaker openings 1017 may be located within an edge of the shell and the first and second shell portions, for example, or wrap from the edge to the back of the shell in the second shell portion. A single speaker opening 1017 may be aligned over a plurality of speakers to accommodate stereo sound or to accommodate base and treble speakers for example. One or more speaker openings may be located in the bezel of the shell for one or more treble speakers while one or more speaker openings may be located in the back of the shell for one or more bass speakers. Alternatively or conjunctively, a portion of the shell 110 may include one or more microphone openings 177 (see FIG. 1) aligned respectively with one or more microphones of the electronic device so that sound may more readily pass through the case 100 to the microphone.

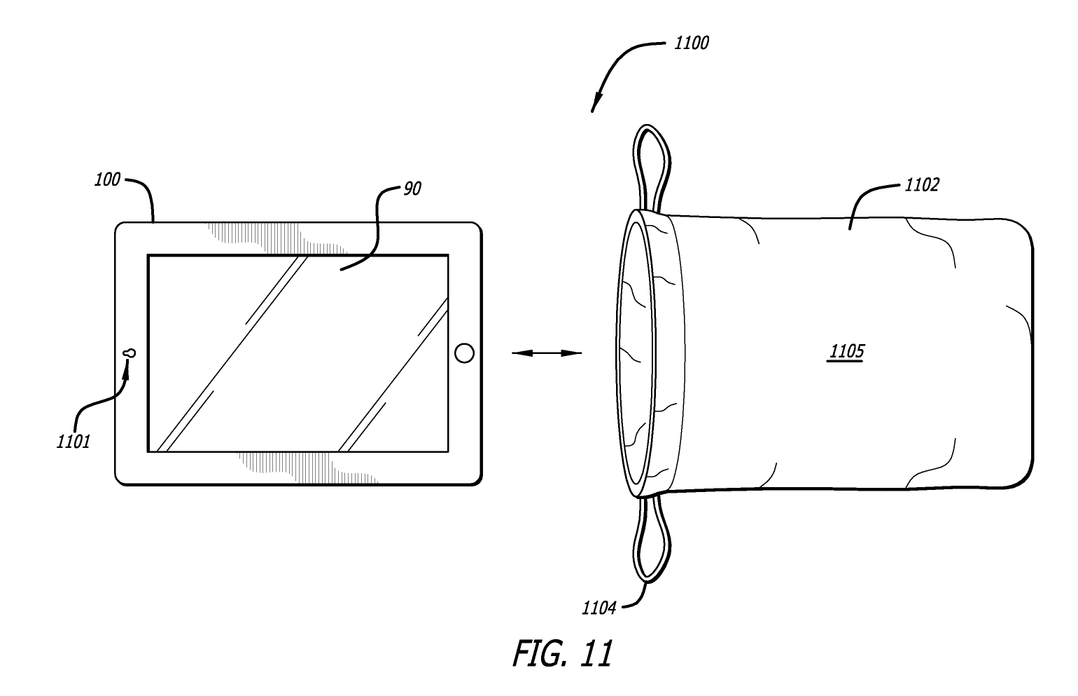

Referring now to FIG. 11, a case 1100 may include the case 100 (including shell and handle) and a draw string bag 1102 to cover over and further protect the electronic device 90. The draw string bag 1002 includes a cloth bag 1105 with one open end, and a draw string 1104 coupled to the bag around the open end. The cloth bag 1105 may be a thick padded cloth bag to protect the electronic device viewable through the rectangular display opening.

The padded cloth bag 1105 and its opening are sufficiently large to insert and receive the case (including the shell and the rotatable handle) and the electronic device. The draw string 1104 can be cinched up to close the open end of the padded cloth bag to fully surround and protect the electronic device when not in use. The padded cloth bag 1105 may be referred to as a travel bag.

While a clock bag may be used to protect the electronic device and its display viewable through the display opening, the case may include a hard flexible cover to cover over the display opening and protect the electronic device.

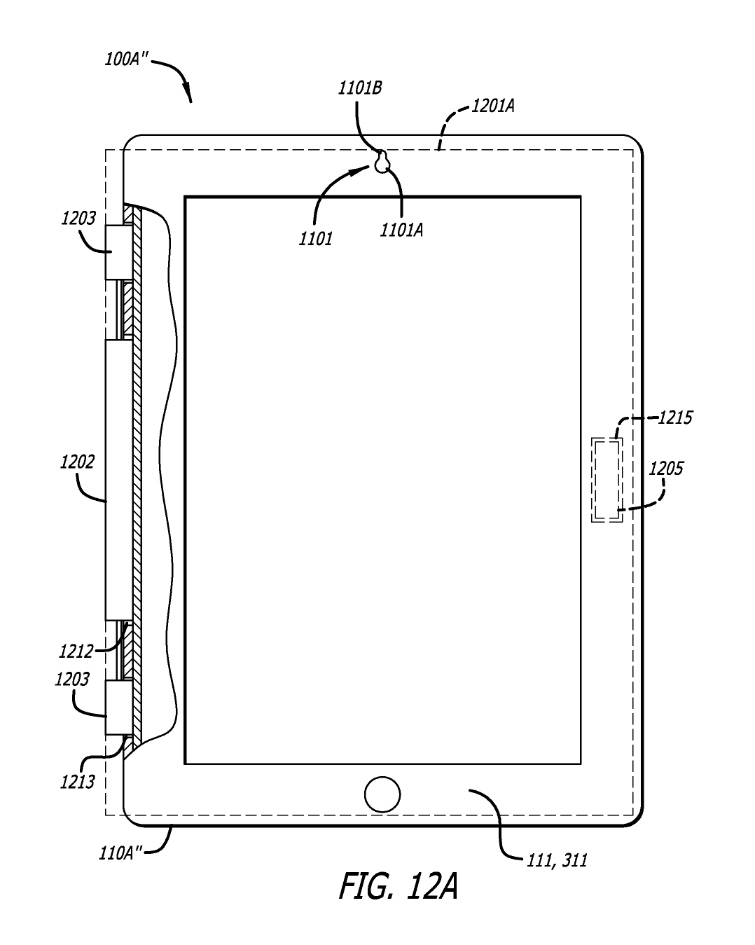

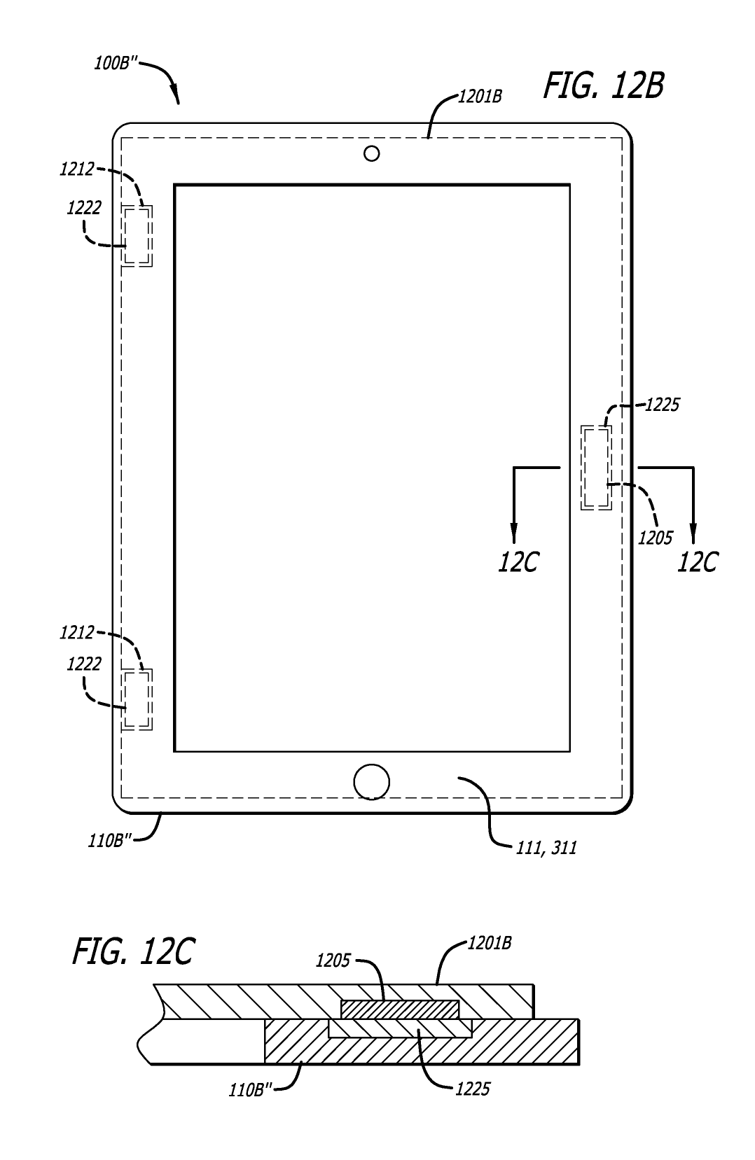

Referring now to FIGS. 12A-12B, a case 100″ may include a shell 110A″,110B″ with features similar to shell 110,110′,310 but with a device to receive a flexible cover 1201 over the display opening 113,313. The flexible cover 1201 includes one or more magnetic fasteners 1202,1205 along one or more edges to couple to ferrous metal/alloy or another magnet. The ferrous metal/alloy or magnet may be provided by the electronic device. Alternatively, the shell may provide the ferrous metal/alloy or an additional magnet to which the one or more magnetic fasteners 1202,1205 may detachably couple. The flexible cover 1201 may include one or more hinges 1213 for which the shell 110,110′,310 may be adapted to accommodate.

In FIG. 12A, a case 100A″ is illustrated with one or more openings 1212 provided along one or more sides of the bezel 111,311 of the shell 110A″ so that they are lined up with the one or more magnets 1202 of the cover 1201A. One or more hinge openings 1213 may be further provided along a side of the bezel to provide clearance for hinges 1213 of the flexible cover 1201. The one or more magnets can detachably couple to metal or magnets of an electronic device through the shell 110A″ by way of the one or more openings 1212.

An opposite side of the flexible cover 1201A may include a magnet fastener and/or a tripping device 1205. The tripping device 1205 may trip a sensor, such as a magnetic sensor or optic sensor for example, to provide an indication that the cover is closed over the electronic device. The shell 110A″ may further include a close sensor opening 1215 in the bezel to allow the closure of the flexible cover to be sensed by a sensor (optical or magnetic) in the electronic device and couple to the electronic device. With a sensor sensing that the flexible cover is closed over the electronic device, the electronic device may power itself off or power itself down into a sleep state. Sensing through the sensor opening 1215 that the flexible cover has been opened by a user, the electronic device may power itself back on or power itself back into an active fully operational state. The close sensor opening 1215 in the bezel may further allow an additional magnet 1205 or other fastener to couple to the electronic device to hold the cover 1201 in a closed position.

In FIG. 12B, a case 100B″ is illustrated with the first shell portion of the shell 110B″ including one or more metal or magnet pieces 1222, 1225 located in one or more sides of the bezel 111,311. The one or more magnets 1202 in the cover 1201B are magnetically coupled to the one or more metal strips/pieces or magnets 1222 to couple the cover 1201B to the shell 110B″.

Referring momentarily to FIGS. 12B-12C, one or more metal or magnet pieces 1225 in an opposite side of the bezel may couple to the magnet 1205 of the cover 1201B. The north/south poles of the one or more magnets 1222,1225 in the shell are respectively aligned with the south/north poles of the magnets 1202,1205 in the cover 1201 to magnetically couple together.

In FIGS. 12A-12B, the flexible cover 1201A,1201B may be turned like a page to uncover over the display opening and a display so that a user may view and control the electronic device in the case. After operation of the electronic device, a user may flip the flexible cover 1201A,1201B back over the display opening to protect the electronic device. The flexible cover 1201A,1201B may roll up or include one or more hinges to fold up out of the way of the display opening in the shell.

Referring back to FIG. 12A, a shell may include one or more optical openings 1101 in the bezel or back surface aligned with one or more optical devices in the electronic device. For example, as a camera opening 1101A and a light sensor opening 1110B adjacent the camera opening 1101A may be provided in the bezel 111,311 of the shell aligned over a camera and a light sensor in the electronic device. An optical opening may be formed by the merger in a camera opening 1101A and a light sensor opening 1101B. The light sensor opening 1101B may be aligned with an ambient light sensor to adjust exposure time of photos or movies taken with a camera of the electronic device. The cover 1201A may cover over an optical opening 1101 so that an ambient light sensor in the electronic device powers off or down the electronic device to a lower power state. An optical opening may be provided in the shell aligned over a flash device to add light to the ambient lighting when taking movies or photos.

As further support to the embodiments described herein, attached hereto as Appendix I are photographs of a first exemplary embodiment of the case. Attached hereto as Appendix II are photographs of a second exemplary embodiment of the case.

It should now be understood that one or more embodiments of the cases described herein may include a handle that rotates relative to a shell, such that a user can reposition the orientation of the electronic device without having to change his or her grip on the handle. Further, the handle and the shell can support the case in a reclined orientation, such that a user does not have to support the electronic device.

It is further noted that terms like “preferably,” “generally,” “commonly,” and “typically” are not utilized herein to limit the scope of the claimed invention or to imply that certain features are critical, essential, or even important to the structure or function of the claimed invention. Rather, these terms are merely intended to highlight alternative or additional features that may or may not be utilized in a particular embodiment of the invention.

For the purposes of describing and defining the one or more embodiments of invention it is additionally noted that the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue.

Having described the invention in detail and by reference to specific embodiments thereof, it will be apparent that modifications and variations are possible without departing from the scope of the invention defined in the appended claims. More specifically, although some aspects of the one or more embodiments of invention are identified herein as preferred or particularly advantageous, it is contemplated that the one or more embodiments of invention are not necessarily limited to these preferred aspects of the one or more embodiments of the invention. Note also that certain features that are described in this specification in the context of separate implementations may also be implemented in combination in a single implementation. Conversely, various features that are described in the context of a single implementation may also be implemented in multiple implementations, separately or in sub-combination. Moreover, although features may be described above as acting in certain combinations and even initially claimed as such, one or more features from a claimed combination may in some cases be excised from the combination, and the claimed combination may be directed to a sub-combination or variations of a sub-combination. Accordingly, the claimed invention should be limited only by patented claims that follow below.

1. A case comprising:
a shell adapted to partially surround an electronic device, the shell including a first shell portion and a second shell portion adapted to couple to the first shell portion, the first shell portion having a display opening to allow a user to view the electronic device and a first camera opening to allow images to be captured by the electronic device in a first direction; and
a rotatable handle adapted to couple to and decouple from the second shell portion of the shell, the rotatable handle adapted to allow the shell to rotate about an axis of rotation, the rotatable handle including an extendable strap assembly to receive a hand of the user.

2. The case of claim 1, further comprising:
a padded cloth bag having an open end adapted to receive the shell and the rotatable handle, the padded cloth bag to surround the shell and the rotatable handle to protect the electronic device viewable through the display opening.

3. The case of claim 1, wherein
the padded cloth bag includes a draw string adapted to cinch up and close the open end of the padded cloth bag.

4. The case of claim 1, wherein
the first shell portion has a button opening to allow the user to push a button of the electronic device.

5. The case of claim 1, wherein
the first shell portion has a moveable button extension within an opening over a push button of the electronic device, the moveable button extension adapted to couple to the push button to control the electronic device.

6. The case of claim 1, wherein
the second shell portion has a second camera opening to allow images to be captured by the electronic device in a second direction differing from the first direction.

7. The case of claim 1, wherein
the shell further has one or more control openings along one or more edges to allow the electronic device to be controlled by the user.

8. The case of claim 7, wherein
the shell further has one or more socket openings along at least one edge to respectively allow one or more sockets of one or more cables to couple to the electronic device.

9. The case of claim 8, wherein
each of the first shell portion and the second shell portion has half openings that align together along the at least one edge to form the one or more control openings and/or the one or more socket openings in the shell.

10. The case of claim 1, wherein
the second shell portion further has a circular opening, and the rotatable handle is adapted to rotatably couple to the second shell portion of the shell over the circular opening.

11. The case of claim 10, wherein
the rotatable handle is further adapted to rotatably couple into and decouple from the circular opening; and
the second shell portion further has a ring portion around the circular opening so that the rotatable handle can freely rotate without interference while a back of electronic device rests against an inner surface of the second shell portion.

12. The case of claim 10, wherein
the second shell portion further has a reinforced portion around the circular opening.

13. The case of claim 12, wherein
the reinforced portion has two pairs of opposing sliding key slots on opposite sides of the circular opening adapted to slidingly receive two pairs of opposing hooks in a retention element of the handle.

14. The case of claim 13, wherein
the reinforced portion further has a groove on one side the circular opening adapted to slidingly receive a latch of the retention element and hold the handle coupled to the shell.

15. The case of claim 14, wherein
a retention bracket of the handle is rotatably coupled to the retention element so that the handle rotates relative to the shell about the axis of rotation.

16. The case of claim 14, wherein
the retention element has a pull flap coupled to and angled out from the latch to allow a finger to pull up on and release the latch from the groove of the second shell portion to release the handle.

17. The case of claim 1, wherein
the first shell portion and the second shell portion are detachably coupled together along a first edge by one or more fasteners.

18. The case of claim 17, wherein
the first shell portion and the second shell portion are pivotally coupled together along a second edge opposite the first edge by one or more hinges.

19. The case of claim 17, wherein
the first shell portion and the second shell portion are detachably coupled together along at least a second edge opposite the first edge by one or more fasteners.

20. The case of claim 17, wherein
the first edge of the first shell portion includes at least one latch and the first edge of the second shell portion includes at least one catch to engage each other to detachably couple the first shell portion and the second shell portion together along the first edge.

21. The case of claim 17, wherein
the first edge of the second shell portion includes at least one latch and the first edge of the first shell portion includes at least one catch to engage each other to detachably couple the first shell portion and the second shell portion together along the first edge.

22. The case of claim 1, wherein
the second shell portion further includes at least one extendable prop adapted to pivot and extend out from the second shell portion to support the case on a surface in a supine orientation.

23-72. (canceled)
